(19) United States
(12) Patent Application Publication
(10) Pub. No.: US 2016/0126380 A1
(43) Pub. Date: May 5, 2016

(54) FLEXIBLE SOLAR PANEL AND METHOD OF FABRICATING THE SAME

(71) Applicant: Sung Un CHANG, Seoul (KR)

(72) Inventor: Sung Un CHANG, Seoul (KR)

(21) Appl. No.: 14/929,093

(22) Filed: Oct. 30, 2015

(30) Foreign Application Priority Data
Oct. 30, 2014 (KR) 10-2014-0149295
May 18, 2015 (KR) 10-2015-0068992
May 21, 2015 (KR) 10-2015-0070792

(51) Int. Cl. H01L 31/0392; H01L 31/02; H01L 25/04; H01L 31/18; H01L 31/048; H01L 31/05

(52) U.S. Cl. CPC H01L 31/03926; H01L 31/048; H01L 31/0516; H01L 25/042; H01L 31/1876; H01L 31/0201

(57) ABSTRACT

Flexible solar panel, flexible solar panel module, and method of fabricating the same. The method includes cutting solar cell into unit cells and processing the unit cells, forming unit electric lines matched up with lower electrodes of each cut and processed unit cell on flexible substrate so that the unit electric lines are arranged at an interval and forming serial lines connecting the positive electrode terminal path and negative electrode terminal path of adjacent unit electric lines so that the unit electric lines are serially connected, coating solder alloy on the unit electric lines, and arranging the lower electrodes of the unit cells and the unit electric lines of the flexible substrate so that the lower electrodes are matched up with the unit electric lines, attaching the lower electrodes and the unit electric lines, and performing soldering processing on the lower electrodes and the unit electric lines by applying heat higher than melting point of the solder alloy.

### CROSS REFERENCE TO RELATED APPLICATION

The present application claims the benefit of Korean Patent Application Nos. 10-2014-0149295, 10-2015-0068992 and 10-2015-0070792 filed in the Korean Intellectual Property Office on Oct. 30, 2014, May 18, 2015 and May 21, 2015, the entire contents of which are incorporated herein by reference.

### BACKGROUND OF THE INVENTION

1. Technical Field

The present invention relates to a flexible solar panel and a method of fabricating the same.

2. Description of the Related Art

A solar panel is a device in which solar cells are connected in series and parallel and an electric current is generated under solar light.

In such a solar panel, a solar cell fabricated in a large area is cut into several unit cells, processed, and connected in series and parallel, thereby obtaining a required voltage and electric current. Such a fabricated solar cell is fabricated by sequentially stacking surface glass, a filler, the solar cell, a filler, and a rear protection material within a strong aluminum frame in order to protect the solar cell against an external impact or bad weather because the solar cell itself is thin and likely to be broken. A solar panel of a single sheet form is fabricated by installing a cable and a power distribution board in such solar cells.

A crystalline silicon panel and an amorphous thin film type panel are being developed. In particular, a panel into which construction materials have been integrated is also developed.

A variety of types of portable solar panels are developed and supplied in line with the development and supply of various solar panels. Accordingly, the solar panel is widely supplied to daily life of the general public.

Despite such a trend, there has not been widely supplied a solar panel which is flexible, has sufficient generating efficiency, can be always carried, and is easy to use. Although some flexible solar panels are developed, they are not widely supplied because they have a high production cost and have much lower generation efficiency than common solar panels despite their flexible characteristic.

### SUMMARY OF THE INVENTION

An object of the present invention is to Provide a flexible solar panel capable of being fabricated at low cost using existing crystalline or non-crystalline solar cells without a change and a method of fabricating the same.

A method of fabricating a flexible solar panel in accordance with an embodiment of the present invention includes a unit cell preparation step of cutting a solar cell into a plurality of unit cells and processing the unit cells; a flexible substrate preparation step of forming a plurality of unit electric lines matched up with the lower electrodes of each cut and processed unit cell on a flexible substrate so that the plurality of unit electric lines is arranged at an interval and forming a plurality of serial lines connecting the positive electrode terminal path and negative electrode terminal path of adjacent unit electric lines so that the plurality of unit electric lines is serially connected; a soldering preparation step of coating a solder alloy on the unit electric lines, and a soldering step of arranging the lower electrodes of the unit cells and the unit electric lines of the flexible substrate so that the lower electrodes are matched up with the unit electric lines, closely attaching the lower electrodes and the unit electric lines, and performing soldering processing on the lower electrodes and the unit electric lines by applying heat higher than a melting point of the solder alloy.

Furthermore, a method of fabricating a flexible solar panel module in accordance with an embodiment of the present invention includes preparing a plurality of flexible solar panels fabricated by the method of fabricating a flexible solar panel and assembling the flexible solar panels so that the flexible solar panel module has a required generation capacity by connecting exposure terminals extended from positive electrode terminal paths and negative electrode terminal paths connected in series on the plurality of flexible solar panels to connectors of a bus terminal.

Furthermore, a flexible solar panel in accordance with an embodiment of the present invention includes a unit cell configured to have a plurality of lower electrodes formed on a bottom surface of the unit cell; and a flexible substrate configured to have a plurality of unit electric lines matched up with the lower electrodes of a unit cell arranged at an interval, to have the plurality of unit electric lines serially connected by a plurality of serial lines connecting the positive electrode terminal path and negative electrode terminal path of the unit electric lines, and to have a solder alloy coated on the unit electric lines, wherein the lower electrodes of the unit cell and the unit electric lines of the flexible substrate are arranged so that the lower electrodes are matched up with the unit electric lines, closely attached, and soldered by applying heat higher than a melting point of the solder alloy.

### BRIEF DESCRIPTION OF THE DRAWINGS

FIG. 1 is a diagram showing a method of fabricating a flexible solar panel in accordance with an embodiment of the present invention.

FIG. 2 is an enlarged plan view of electric lines formed in a flexible substrate of FIG. 1.

FIG. 3 is a cross-sectional view showing the state in which unit cells and a flexible substrate have been arranged.

FIG. 4 is a cross-sectional view showing the state in which protection layers have been installed up and down after the unit cells and the flexible substrate are subjected to soldering processing.

FIG. 5 is a cross-sectional view showing the state in which a protection layer and an adhesive layer have been disposed on the bottom surface of the flexible substrate of FIG. 4.

FIG. 6 is a plan view showing an example of a flexible solar panel module in accordance with an embodiment of the present invention.

FIG. 7 is a block diagram of a charging circuit unit.

FIG. 8 is a block diagram showing the parallel deployment of bus terminals included in the flexible solar panel module in accordance with an embodiment of the present invention.

FIG. 9 is a block diagram showing the serial deployment of bus terminals included in the flexible solar panel module in accordance with an embodiment of the present invention.

FIG. 10 is a block diagram showing the serial and parallel mixed deployment of bus terminals included in the flexible solar panel module in accordance with an embodiment of the present invention.

FIG. 11 is an exemplary plan view showing the text form assembly state of the flexible solar panel module in accordance with an embodiment of the present invention.

### DETAILED DESCRIPTION

Some embodiments of the present invention are described in detail with reference to the accompanying drawings. A solar panel, a solar panel module, and various methods of assembling the solar panel and the solar panel module described in the embodiments of the present invention are exemplary, and the present invention is not restricted by them.

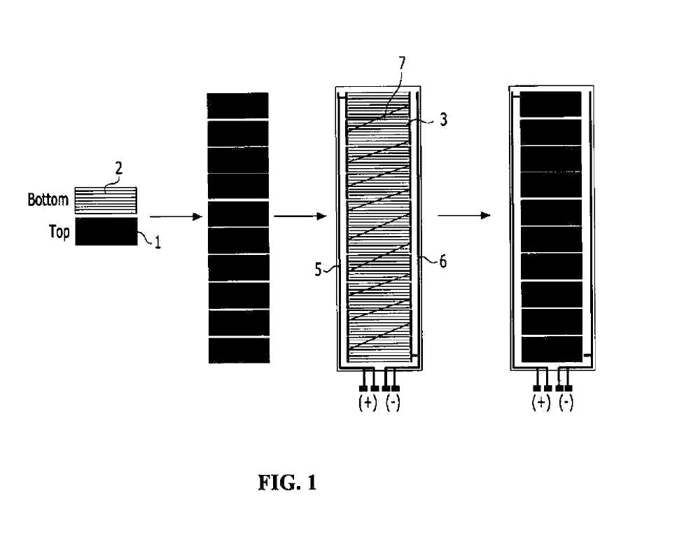

FIG. 1 is a diagram showing a method of fabricating a flexible solar panel 10 in accordance with an embodiment of the present invention. The method may be divided into a unit cell preparation step, a flexible substrate preparation step, a soldering preparation step, and a soldering step.

The unit cell preparation step is a process of cutting a solar cell fabricated in a large area into a plurality of unit cells 1 and processing the plurality of unit cells. In this case, the solar cell in accordance with an embodiment of the present invention may be applied to all of existing crystalline or non-crystalline solar cells. A plurality of lower electrodes 2 in which an electric current generated by solar light generation flows is formed on a bottom surface of the unit cell 1 (i.e., a plane opposite a plane of incidence of solar light). The plurality of lower electrodes 2 may be formed in parallel, and adjacent lower electrodes 2 have opposite polarities.

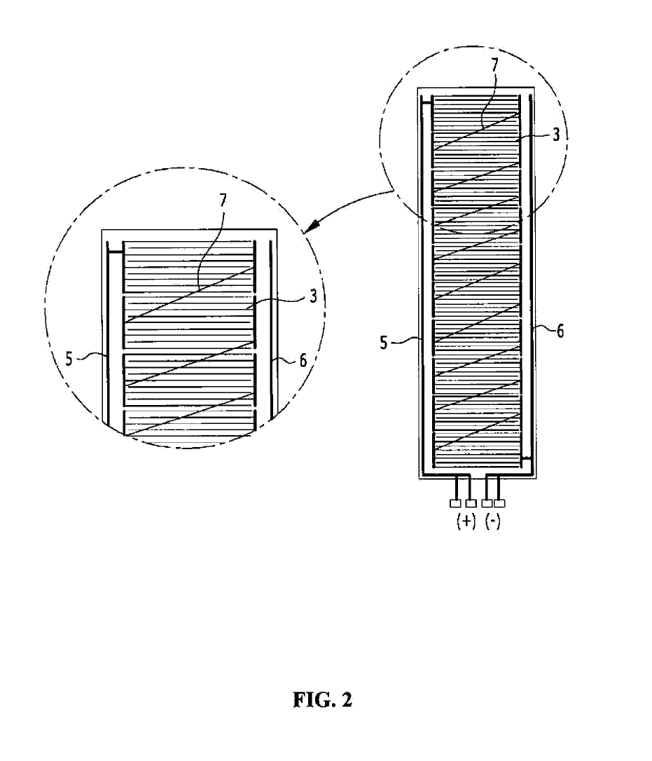

The flexible substrate preparation step is a process of preparing a flexible substrate P so that the plurality of unit cells 1 cut and processed as described above are bonded together and electrically connected to form a single solar panel. As shown in FIG. 2, unit electric lines 3 bonded to the lower electrodes 2 of the unit cell 1 are formed on the flexible substrate P. The unit electric lines 3 are matched up with the lower electrodes 2 of the unit cell 1, and adjacent lower electrodes 2 have opposite polarities. Accordingly, the unit electric lines 3 are divided into positive electrode terminal path 5 and a negative electrode terminal path 6 which are alternately arranged. The positive electrode terminal path 5 and the negative electrode terminal path 6 are arranged on both sides of each unit cell 1 so that the electric lines are efficiently arranged. Furthermore, the unit cells 1 need to be serially connected because the amount of voltage and electric current generated by each unit cell 1 is small. To this end, a plurality of serial lines 7 connecting the positive electrode terminal path 5 and negative electrode terminal path 6 of the unit electric lines 3 is formed in the flexible substrate P. Accordingly, the plurality of unit electric lines 3 is serially connected. Since the serial lines 7 need to be separated from the unit electric lines 3, they may be formed on the other surface of the flexible substrate P (i.e., a surface in which the unit electric lines are not formed) through a via hole, for example. For reference, the number of unit cells 1 bonded to a single flexible substrate P is determined to generate a required voltage. For example, the number of unit cells 1 may be determined to generate a generation voltage, such as 1, 2, 3, 5, or 10 V in unit of 0.5 V.

After the flexible substrate P is prepared as described above, a solder alloy is coated on the unit electric lines 3 through the soldering preparation step.

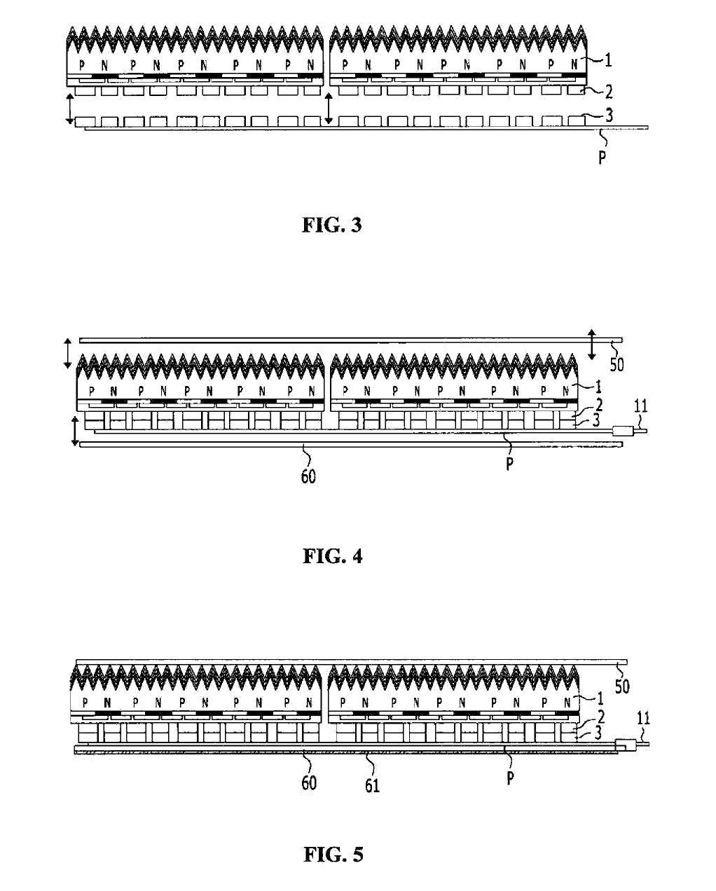

Furthermore, the soldering step is a process of closely arranging the plurality of unit cells 1 so that the lower electrodes 2 of each unit cell 1 are matched up with the unit electric lines 3 of the flexible substrate P and performing soldering processing on the lower electrodes 2 and the unit electric lines 3 by applying heat higher than the melting point of the solder alloy. Such a process is illustrated in more detail in FIGS. 3 to 5. Productivity can be greatly improved because the flexible solar panel 10 is completed through a simple process of directly soldering the plurality of unit cells 1 on the unit electric lines 3 formed on the flexible substrate P as described above. Such a soldering step may be performed in a reflow oven.

Furthermore, the flexible solar panel 10 in accordance with an embodiment of the present invention can be flexibly folded along the boundary between the unit cells 1 because the unit electric lines 3 to which each unit cell 1 are bonded have a specific interval. Accordingly, although existing crystalline or non-crystalline solar cells rarely having flexibility are subjected to soldering processing for the flexible substrate P without a change, the flexible solar panel 10 may be randomly formed to have a bendable form by geometrically designing the unit electric lines 3.

Furthermore, the method may further include a step of stacking a transparent protection film on a top surface of the flexible solar panel 10 on which soldering processing has been performed. If the transparent protection film is coated on the top surface of the flexible solar panel 10, a surface on which solar light is incident can be prevented from being damaged or contaminated by moisture or an impact and can easily transmit solar light.

Furthermore, as shown in FIG. 5, a transparent protection layer may be further formed under the flexible solar panel 10 in order to prevent a contamination and damage. An adhesive layer or a magnet layer may be formed on the transparent protection layer on the bottom surface of the flexible solar panel 10. Accordingly, the flexible solar panel 10 can be used for various purposes by easily attaching the flexible solar panel 10 to materials, such as wood, metal, and a synthetic resin plate, and fabric.

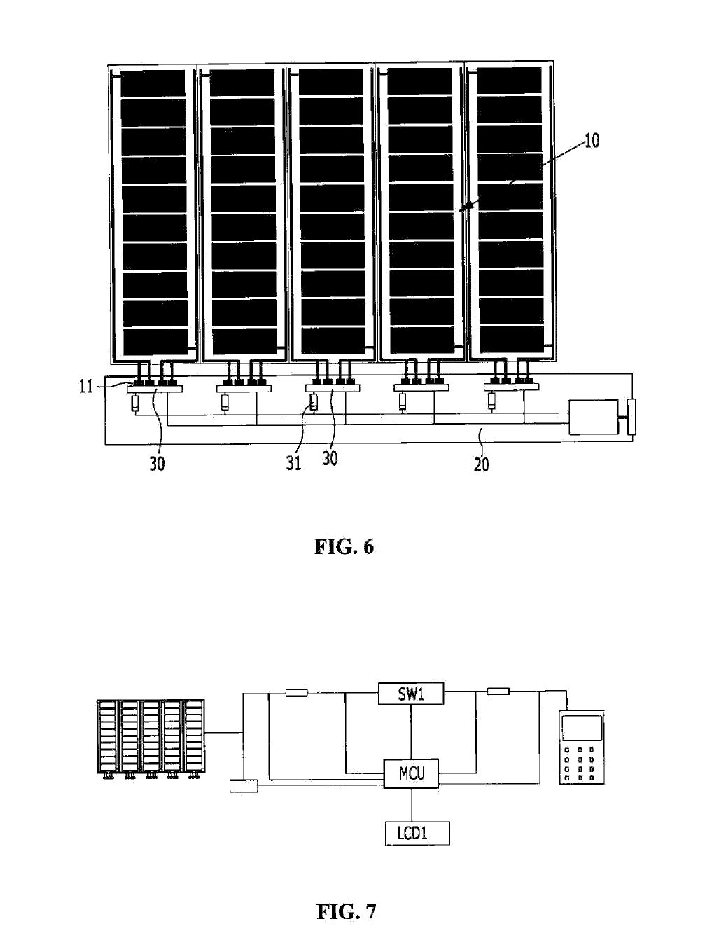

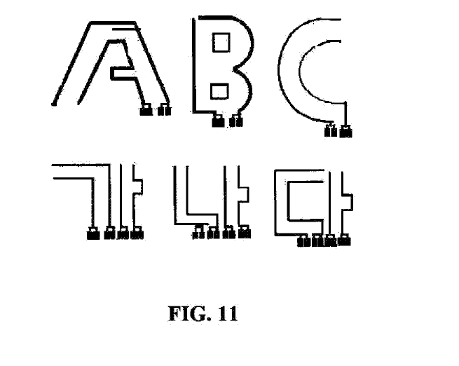

As shown in FIG. 6, a proper number of the flexible solar panels 10 fabricated through such a fabrication process may be modulated in order to obtain a required generation capacity by combining methods of connecting the flexible solar panels 10 in various ways. Various embodiments of such a flexible solar panel module are shown in FIGS. 6 to 10.

A process of fabricating such a flexible solar panel module is described below. First, a plurality of the solar panels fabricated by the aforementioned fabrication method is prepared. The plurality of prepared flexible solar panels 10 is assembled so that a required generation capacity is obtained by connecting exposure terminals 11, extended from the positive electrode terminal paths 5 and the negative electrode terminal paths 6 connected in series on the plurality of flexible solar panels 10, to the connectors 30 of a bus terminal 20, thereby completing the flexible solar panel module.

In this case, the entire flexible solar panel module may have flexibility by fabricating the bus terminal 20 including the connectors 30 using a soft material.

Furthermore, a charging circuit unit may be further configured so that the flexible solar panel module in accordance with an embodiment of the present invention is applied to the charging device of a smart device, such as a smart phone. That is, as shown in FIG. 7, the flexible solar panel module may be configured to include a charging circuit unit including a voltage comparison circuit between the bus terminal 20 of the flexible solar panel module and an external load.

In particular, the charging circuit unit is characterized in that an initial charging voltage thereof remains as a charging voltage when the initial charging voltage is set in a smart device itself, such as a smart phone, when the smart device is charged. Accordingly, the charging circuit unit can prevent an inefficient phenomenon in which the smart phone is charged with a low voltage if the flexible solar panel module is shaded or an output voltage is greatly lowered due to a change of an incident angle of solar light.

More specifically, the charging circuit unit is configured to include a micro control unit (MCU) configured to receive the voltage signal of a smart device and the voltage signal of the flexible solar panel module, compare the voltage signal of the smart device with the voltage signal of the flexible solar panel module, and perform operation on a result of the comparison, a control unit SW1 configured to generate a reset signal if, as a result of the comparison and operation of the MCU, the voltage signal of the smart device is lower than that of the flexible solar panel module, and a display unit LCD1 configured to display the current operating state and charging state of the smart device.

Accordingly, if a generation voltage is significantly lowered due to a movement of clouds or a motion of a person while the flexible solar panel module is charged with a specific voltage, the MCU newly sets the initial charging voltage of the smart device through a reset operation. Accordingly, the generation voltage is recognized as normally becoming a solar light generation voltage newly, thereby enabling a smooth charging operation.

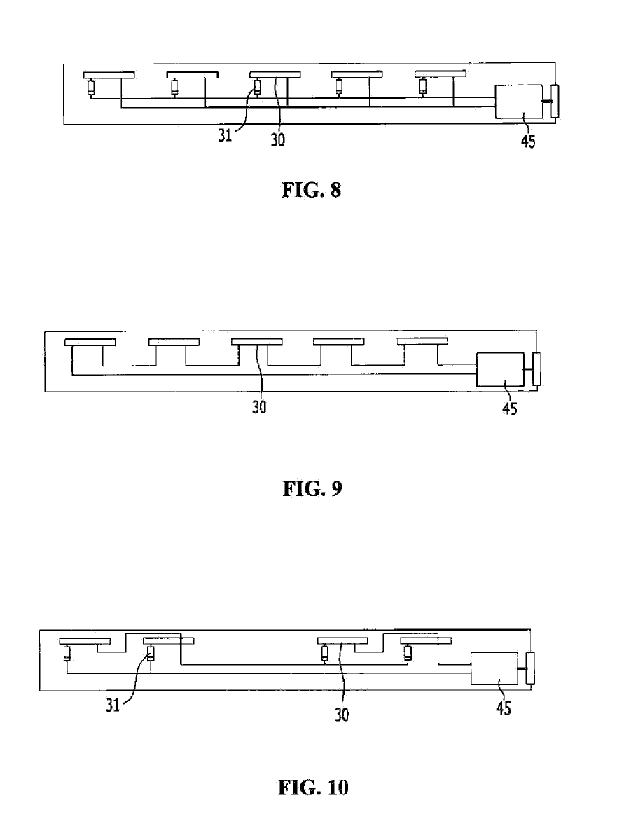

Furthermore, the flexible solar panel module in accordance with an embodiment of the present invention may be properly designed to have a total output voltage by properly setting the circuit wiring of the flexible solar panel module in a serial type, a parallel type or a mixed type of them when the connectors 30 of the bus terminal 20 to which the exposure terminals 11 of each flexible solar panel 10 are connected are collected at a single junction box 45. FIGS. 8 to 10 show configurations in which a plurality of the bus terminals 20 included in the respective flexible solar panel modules is connected to the junction box 45 in a parallel form, a serial form, and a serial and parallel mixed form. Furthermore, various devices can be prevented from being damaged by a back electromotive force generated by an instant potential difference and generating efficiency can be improved by installing an inverse voltage prevention element 31 between the plurality of bus terminals 20 and the junction box 45.

The flexible solar panel module in accordance with an embodiment of the present invention may be configured in a pictogram form which represents Hangul, English, various other letters, a building, or an object, as shown in an example of FIG. 11 by designing the array form of the flexible substrate P. Accordingly, a user may attach the flexible solar panel module implemented in a desired pictogram form to a cloth, a hat, a vest, a backpack, a camping tent, an outdoor wall, or a sculpture so that the flexible solar panel module is matched up with a surrounding environment or a specific message or information is delivered.

An embodiment of the present invention has an advantage in that productivity is significantly improved because the flexible solar panel is completed by forming a plurality of the unit cells on the unit electric lines formed on the flexible substrate through a simple soldering processing process.

Furthermore, the unit electric lines to which each unit cell is bonded can be flexibly folded along the boundary between the unit cells because the unit electric lines have a specific interval although existing crystalline or non-crystalline solar cells are subjected to soldering processing on the flexible substrate without a change. Accordingly, there is an advantage in that the flexible solar panel can be fabricated in a random and bendable form by designing the geometrical array of the unit electric lines.

1. A method of fabricating a flexible solar panel, comprising:
a unit cell preparation step of cutting a solar cell into a plurality of unit cells and processing the unit cells;
a flexible substrate preparation step of forming a plurality of unit electric lines matched up with lower electrodes of each cut and processed unit cell on a flexible substrate so that the plurality of unit electric lines is arranged at an interval and forming a plurality of serial lines connecting a positive electrode terminal path and negative electrode terminal path of adjacent unit electric lines so that the plurality of unit electric lines is serially connected;
a soldering preparation step of coating a solder alloy on the unit electric lines, and
a soldering step of arranging the lower electrodes of the unit cells and the unit electric lines of the flexible substrate so that the lower electrodes are matched up with the unit electric lines, closely attaching the lower electrodes and the unit electric lines, and performing soldering processing on the lower electrodes and the unit electric lines by applying heat higher than a melting point of the solder alloy.

2. The method of claim 1, wherein the soldering step is performed in a reflow oven.

3. The method of claim 1, further comprising a step of stacking a transparent protection film on a top surface of the soldering-processing flexible solar panel.

4. The method of claim 1, further comprising a step of forming a transparent protection layer configured to protect a bottom of the flexible solar panel.

5. The method of claim 4, wherein an adhesive layer or a magnet layer is further formed on a surface of the transparent protection layer.

6. A method of fabricating a flexible solar panel module, comprising:
preparing a plurality of flexible solar panels fabricated by a method of fabricating a flexible solar panel according to claim 1; and
assembling the flexible solar panels so that the flexible solar panel module has a required generation capacity by connecting exposure terminals extended from positive electrode terminal paths and negative electrode terminal paths connected in series on the plurality of flexible solar panels to connectors of a bus terminal.

7. The method of claim 6, wherein the bus terminal is made of a soft material.

8. The method of claim 6, wherein the connectors of the bus terminal are connected to a junction box in a serial form, a parallel form or a mixed form of the serial and parallel forms.

9. A flexible solar panel, comprising:
a unit cell configured to have a plurality of lower electrodes formed on a bottom surface of the unit cell; and
a flexible substrate configured to have a plurality of unit electric lines matched up with lower electrodes of a unit cell arranged at an interval, to have the plurality of unit electric lines serially connected by a plurality of serial lines connecting a positive electrode terminal path and negative electrode terminal path of the unit electric lines, and to have a solder alloy coated on the unit electric lines,
wherein the lower electrodes of the unit cell and the unit electric lines of the flexible substrate are arranged so that the lower electrodes are matched up with the unit electric lines, closely attached, and soldered by applying heat higher than a melting point of the solder alloy.

10. The flexible solar panel of claim 9, further comprising a transparent protection film stacked on a top surface of the flexible solar panel.

11. A flexible solar panel module, comprising:
a flexible solar cell panel each configured to comprise:
a unit cell configured to have a plurality of lower electrodes formed on a bottom surface of the unit cell, and
a flexible substrate configured to have a plurality of unit electric lines matched up with lower electrodes of the unit cells arranged at an interval, to have the plurality of unit electric lines serially connected by a plurality of serial lines connecting a positive electrode terminal path and negative electrode terminal path of the unit electric lines, and to have a solder alloy coated on the unit electric lines, wherein the lower electrodes of the unit cell and the unit electric lines of the flexible substrate are arranged so that the lower electrodes are matched up with the unit electric lines, closely attached, and soldered by applying heat higher than a melting point of the solder alloy; and
a plurality of connectors configured to comprise a bus terminal connected to exposure terminals extended from the positive electrode terminal paths and the negative electrode terminal paths connected in series on a plurality of the flexible solar panels.

12. The flexible solar panel module of claim 11, further comprising a junction box to which the connectors of the bus terminal are connected in a serial form, a parallel form or a mixed type of the serial and parallel forms.
